(19) United States
(12) Patent Application Publication
(10) Pub. No.: US 2025/0362352 A1
(43) Pub. Date: Nov. 27, 2025

(54) ELECTROCHEMICAL MONITORING SYSTEM ADJUSTMENT

(71) Applicants: Zhiwu Zheng, Boston, MA (US); Shella Patricia Seidel, Jamaica Plain, MA (US); Sue Zheng, Melrose, MA (US); Atula Yellepeddi, Medford, MA (US)

(72) Inventors: Zhiwu Zheng, Boston, MA (US); Shella Patricia Seidel, Jamaica Plain, MA (US); Sue Zheng, Melrose, MA (US); Atula Yellepeddi, Medford, MA (US)

(21) Appl. No.: 19/210,883

(22) Filed: May 16, 2025

Related U.S. Application Data
(60) Provisional application No. 63/651,566, filed on May 24, 2024.

(51) Int. Cl. G01R 31/389; G01R 31/367; G01R 31/3835; G01R 31/392

(52) U.S. Cl. CPC G01R 31/389; G01R 31/367; G01R 31/3835; G01R 31/392

(57) ABSTRACT

In an example, an electrochemical monitoring system for determining one or more parameters of interest of an electrochemical cell can include measurement circuitry, which can be configured to obtain, for a plurality of specified alternating current (AC) frequencies: (1) a first AC voltage measurement across nodes which can be coupleable to the electrochemical cell, and (2) a second AC voltage measurement across a sensing impedance which can be elicited in response to the AC stimulus. The sensing impedance can be coupled in series with the electrochemical cell. The electrochemical monitoring system can also include a controller circuit, which can be configured to jointly estimate model parameters corresponding to an equivalent circuit model (ECM) of a combination of the electrochemical cell and the sensing impedance, such as using the first and second AC voltage measurements for the plurality of specified AC frequencies.

### CLAIM OF PRIORITY

This patent application claims the benefit of priority of Zheng et al., U.S. Provisional Patent Application Ser. 63/651,566, entitled “FEATURES AND MEASUREMENT CALIBRATION FOR EIS HEALTH MONITORING OF ELECTROLYZERS,” filed on May 24, 2024 (Attorney Docket No. 3867.C57PRV), which is hereby incorporated by reference herein in its entirety.

### TECHNICAL FIELD

This document pertains generally, but not by way of limitation, to Electrochemical Impedance Spectroscopy (EIS), and specifically to EIS monitoring of electrolysis cells.

### BACKGROUND

Modern systems can use electrochemical cells, such as energy storage systems and electrolysis systems. Energy storage systems can include batteries or fuel cells, and can be a main power source or an auxiliary power source. Electrolysis systems can include electrolysis cells, such as for driving a chemical reaction using electrical energy. Examples of such modern systems can include consumer electronics, industrial electronics, passenger cars, industrial trucks, and industrial processing plants. Monitoring a parameter of a cell, such as the state of charge (SoC) or the state of health (SoH), can help ensure reliable operation of the system and avoid unnecessary damage to the cell, such as due to overheating.

### SUMMARY

In an example, an electrochemical monitoring system for determining one or more parameters of interest of an electrochemical cell can include measurement circuitry, which can be configured to obtain, for a plurality of specified alternating current (AC) frequencies: (1) a first AC voltage measurement across nodes which can be coupleable to the electrochemical cell, the first AC voltage measurement can be elicited in response to an AC stimulus injected through the electrochemical cell, and (2) a second AC voltage measurement across a sensing impedance which can be elicited in response to the AC stimulus. The sensing impedance can be coupled in series with the electrochemical cell. The electrochemical monitoring system can also include a controller circuit, which can be configured to jointly estimate model parameters corresponding to an equivalent circuit model (ECM) of a combination of the electrochemical cell and the sensing impedance, such as using the first and second AC voltage measurements for the plurality of specified AC frequencies. The first and second AC voltage measurements can contain magnitude and phase information, the phase information can be relative to a reference phase derived from the AC stimulus.

In an example, a method for determining one or more parameters of interest of an electrochemical cell can include, at a plurality of specified alternating current (AC) frequencies: (1) generating an AC stimulus for delivery to an electrochemical cell, (2) measuring an AC voltage across the electrochemical cell in response to the AC stimulus, and (3) measuring an AC voltage across a sensing impedance in response to the AC stimulus. The sensing impedance can be coupled in series with the electrochemical cell. The method can also include jointly estimating model parameters corresponding to an equivalent circuit model (ECM) of the electrochemical cell and the sensing impedance, such as using the plurality of AC voltage measurements.

### BRIEF DESCRIPTION OF THE DRAWINGS

In the drawings, which may not be drawn to scale, like numerals may describe substantially similar components throughout one or more of the views. Like numerals having different letter suffixes may represent different instances of substantially similar components. The drawings illustrate generally, by way of example but not by way of limitation.

FIG. 1 is a block diagram of an example of portions of an electrolyzer system.

FIG. 2 is a block diagram of an example of portions of an electrolytic cell.

FIG. 3 shows an example of portions of an equivalent circuit model for an electrochemical cell.

FIG. 4 shows an example of portions of an equivalent circuit model for a sensing impedance.

FIG. 5 shows an example of a Nyquist plot of an ideal electrolytic cell.

FIG. 6A shows an example of an uncalibrated impedance spectrum chart of an electrochemical cell.

FIG. 6B shows an example of a calibrated impedance spectrum chart of an electrochemical cell.

FIG. 7 shows an example of portions of an electrochemical monitoring system.

FIG. 8 shows an example of portions of a block diagram of an electrochemical monitoring system.

FIG. 9A shows an example of a Nyquist plot of a baseline cell.

FIG. 9B shows an example of a Nyquist plot of an anomalous cell.

FIG. 10 shows an example of portions of a method for operating an electrochemical monitoring system.

FIG. 11 is a block diagram of an example of portions of a machine upon which one or more portions of the present disclosure may be implemented.

### DETAILED DESCRIPTION

One approach to estimate or measure a parameter of an electrochemical cell, such as the SoC or SoH, is electrochemical impedance spectroscopy (EIS). EIS can include measuring the impedance (e.g., DC resistance, AC impedance, complex impedance (e.g., the AC impedance including a real and imaginary component based upon the phase relationship of voltage and current)) of a cell arrangement of electrochemical cells at one or more frequencies. The determined complex impedance of a portion of (e.g., a single cell, a group of cells, such as can include a series and/or parallel combination) the cell arrangement can be used to obtain information about the SoC and SoH of a portion of the cell arrangement. The cell arrangement can include one or more electrochemical cells. An electrochemical cell can include a galvanic cell (e.g., voltaic cell), which can convert chemical energy to electrical energy, or an electrolytic cell (e.g., electrolysis cell), which can use electrical energy to drive a chemical reaction. Examples of galvanic cells can include batteries and or fuel cells. Examples of electrolytic cells can include a water electrolysis cell, which can produce hydrogen using electrical power.

Making an EIS measurement can include measuring a current through the cell arrangement, a voltage across the cell arrangement, or both. A measured current and voltage can be used to determine the complex impedance of the cell arrangement. Measuring a current can include measuring a voltage across a resistance (e.g., a shunt resistance), such as can be in series with the cell arrangement. The complex impedance of the cell arrangement at one or more specified EIS frequencies can be used to determine or infer one or more EIS parameters (e.g., EIS properties).

The present inventors have recognized, among other things, that it can be desirable to analyze the voltage across an electrochemical cell in response to one or more frequencies of stimulus signals, alternatively or in addition to analyzing the impedance of the electrochemical cell at one or more frequencies. In an approach, the impedance of an electrochemical cell can be determined by dividing the voltage across the electrochemical cell by the current through the electrochemical cell. However, this can be benefitted by current information of a specified precision, which can be provided by one or more of a precision sensing impedance or a calibrated sensing impedance. This sensing impedance can be one or more of expensive, time consuming to calibrate, or difficult to calibrate without special equipment. By analyzing the voltage across the electrochemical cell directly, a calibrated sensing impedance need not be required.

The present inventors have also recognized, among other things, that it can be desirable to analyze a voltage across a sensing impedance, such as in combination with analyzing the voltage across the electrochemical cell. The voltage across the sensing impedance can provide an indication of the magnitude of the stimulus signal. One or more measurements can be made, and the measured data can be fit to a specified model, such as an equivalent circuit model (ECM). For example, a numerical fitting or optimization technique an be used. The model parameters can then be used to infer information about the electrochemical cell (e.g., SoC, SoH), such as directly or following further processing. In this way, one or more “EIS” parameters or properties can be determined without performing an impedance measurement.

An electrolyzer can include one or more electrolytic cells. An electrolytic cell can have three component parts: an electrolyte, two electrodes (a cathode and an anode), and bipolar plates to distribute the gases evenly over the electrolyte. The electrolyte can be a solution of water or other solvents in which ions are dissolved. Molten salts, such as sodium chloride, can also be used as electrolytes. When driven by an external voltage applied to the electrodes, the ions in the electrolyte can be attracted to an electrode with the opposite charge, where charge-transferring (also called faradaic or redox) reactions can take place. With an external electrical potential (e.g., voltage) of correct polarity and sufficient magnitude, an electrolytic cell can decompose a normally stable, or inert, chemical compound in the solution. The electrical energy provided can produce a chemical reaction that would otherwise not occur. Water, particularly when ions are added (salt water or acidic water), can be electrolyzed (subject to electrolysis). When driven by an external source of voltage, H+ ions can flow to the cathode to combine with electrons, which can produce hydrogen gas in a reduction reaction. Likewise, OH− ions can flow to the anode to release electrons and an H+ ion, which can produce oxygen gas in an oxidation reaction.

A system that generates hydrogen through electrolysis can be called an electrolyzer or a hydrolyzer. A power generation system can produce a voltage (e.g., between 50V and 200V) and a current (e.g., 100 A to 4000 A) that can be provided to a cell stack that includes electrolytic cells. With water as the other input, the cell stack can produce hydrogen and oxygen as outputs. If the source of power is a renewable such as solar, wind, or hydroelectric, then the entire cycle can be completely carbon free. Electrolyzer cells can be electrically connected in series, parallel, or both.

Electrochemical cell types can include Alkaline, exchange membrane, and solid-oxide electrolysis cells. Exchange membrane cells can be either anion exchange membranes or proton exchange membranes (PEM). This disclosure is described as it applies to proton exchange membrane electrolyzers, but the disclosure is similarly applicable to anion exchange membrane electrolyzers, as well as other types of electrochemical cells (e.g., electrolysis cells, fuel cells, battery cells).

During the operation of the electrolyzer, a number of faults can develop in any of the PEM cells. These might include degradation with time due to electrode or membrane depositions or thinning, irregular catalyst coatings, PTL protective coating deficiencies or membrane pinholes. These all can have an effect on the impedance of the cell at different frequencies. For instance, in certain cases, under a high-current load of 3 A/cm2 over 1000 hours, the anode polarization resistance at low frequencies can increase substantially, whereas the series resistance (whose effect dominates at high frequency) can decrease slightly.

Commercial electrolyzers can have limited online monitoring capabilities. While some process parameters like temperature, flow-rate and pressure of the water input, and the oxygen and hydrogen produced, are measured, these parameters may not provide sufficient insight to inform what predictive maintenance may be required. This also has implications for the lifetime and uptime of the electrolysis systems. The ability to predict failures can improve the ability for the operator to keep the H2 generator online by replacing the module or performing preventative maintenance prior to a stack failure that would cause the system to be suddenly taken out of service.

In an approach, Electrochemical Impedance Spectroscopy (EIS) techniques can use specified, calibrated, or measured values for system components. Specifically, these approaches can use voltage measurements across the device under test (DUT) and a sensing impedance (SNS) to estimate impedance of the DUT. This method can assume the sensing impedance is a specified value R, but in reality, the sensing impedance can include inductive components (ZSNS˜R+jωL, where L may not be specified). In an example, L can correspond to a parasitic inductance of the sensing impedance. This discrepancy can cause or contribute to measurement errors, particularly at higher frequencies, which can lead to inaccurate health monitoring and performance assessment of the DUT, such as the electrolyzer cells.

In an approach, the sensing impedance can be calibrated (e.g., to determine L, R, or both). For example, the sensing impedance can be measured using a system with a specified precision. However, this can be one or more of expensive, less accurate than desirable, or difficult to scale. Additionally, the system performance can constrained by the accuracy of the reference measurement system, which can lower-bound the estimation error. Furthermore, the sensing impedance's characteristics may change with temperature or other environmental factors during operation (e.g., in situ parasitic effects), which may not be corrected for by an initial calibration. Accordingly, it can be desirable to determine one or more properties of an electrochemical cell without requiring a calibrated sensing impedance.

While the disclosed techniques are provided in the context of an electrolyzer as a device under test (DUT), performance or impedance of any other component can be similarly measured using similar techniques.

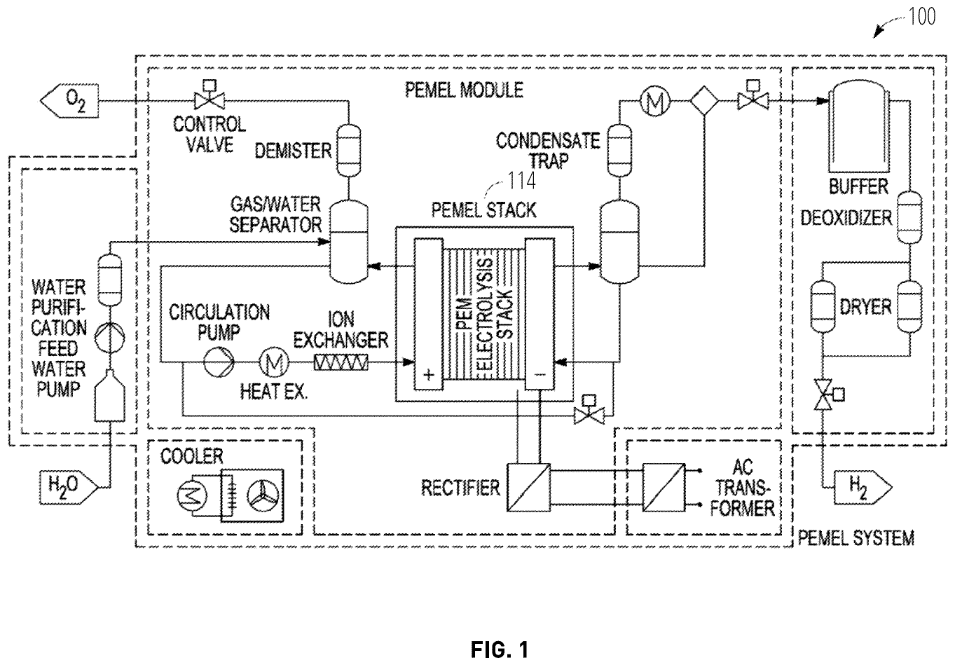

FIG. 1 is a block diagram of an example of portions of an electrolyzer system 100. The electrolyzer system 100 includes a PEMEL stack 114. The PEMEL stack 114 includes one or more cells connected electrically in parallel, series, or both. One or more cells in the PEMEL stack 114 can be driven by a common voltage source.

One or more of the electrolytic cells can include an electrolyte coupled to receive a solution (e.g., water) and two electrodes. One or more of the electrolytic cells can output oxygen and hydrogen. The rate of output can depend on the power received by the electrodes of the cell. In some cases, a higher power can generate oxygen and hydrogen at a faster rate, but this can reduce durability of the system. On the other hand, a lower power can generate oxygen and hydrogen at a slower rate, which can increase durability of the system.

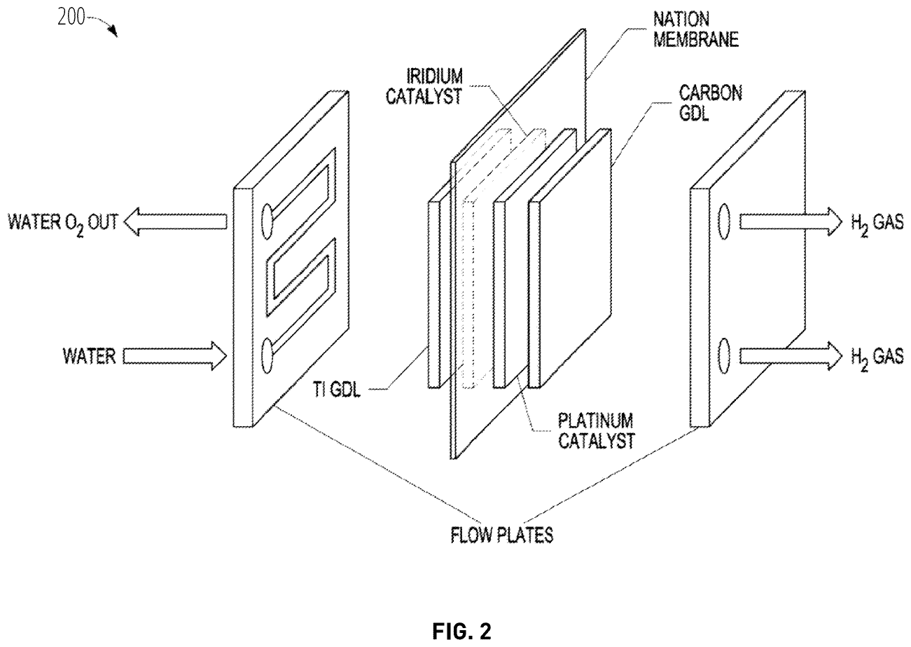

FIG. 2 is a block diagram of an example of portions an electrolytic cell 200. Specifically, FIG. 2 shows the basic representative structure of a single cell of a PEMEL stack 114 as shown in FIG. 1. A PEMEL stack 114 can consist of multiple cells laid in series, as shown in FIG. 1, though the cells can alternately be arranged in parallel. FIG. 2 shows the basic electrochemistry and production of H2 in the electrolytic cell 200. The full electrolyzer includes the PEMEL stack 114 along with control and power circuitry, as shown in FIG. 1.

In some examples, the electrolyzer system 100 is a 1 MW electrolyzer and can have up to 130 cells in the PEMEL stack 114, with a voltage drop of 2.2V/cell, for an overall voltage of about 300V across the PEMEL stack 114. The electrolyzer system 100 can have a current density per plate area up to 3 A/cm2, and a plate area of about 1250 cm2 for a total current through the electrolyzer system 100 of 3750 A. The per-cell impedance can be on the order of 170 uOhm/cell.

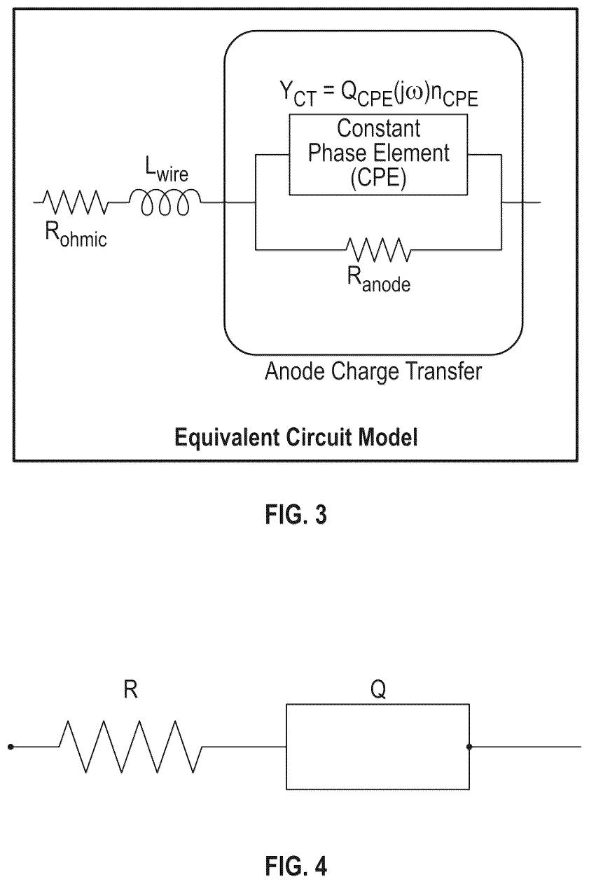

FIG. 3 shows an example of portions of an equivalent circuit model for an electrochemical cell, such as an electrolytic cell. FIG. 3 shows that the ECM can include one or more parameters. R_ohmic can represent the electronic resistance of cell components (e.g., an ohmic resistance of the metallic electrochemical cell component). L_wire can represent inductive components of the cell. R_anode can represent the anodic polarization resistance. Q_CPE can represent the pseudo-capacitive interface, n_CPE can represent the constant phase element parameter. j can represent the imaginary number (e.g., the square root of −1). ω can represent the angular frequency of the AC stimulus signal.

FIG. 4 shows an example of portions of an equivalent circuit model for a sensing impedance. FIG. 4 shows that the ECM can include one or more parameters. R can represent the resistance of the sensing impedance. Q can represent the reactance, such as an inductance (e.g., a positive Q) or a capacitance (e.g., a negative Q). In an example, Q can be a function of frequency (e.g., Q(ω)). Alternatively or additionally, R can be a function of frequency. The impedance profile of the sensing impedance can have any profile as a function of frequency.

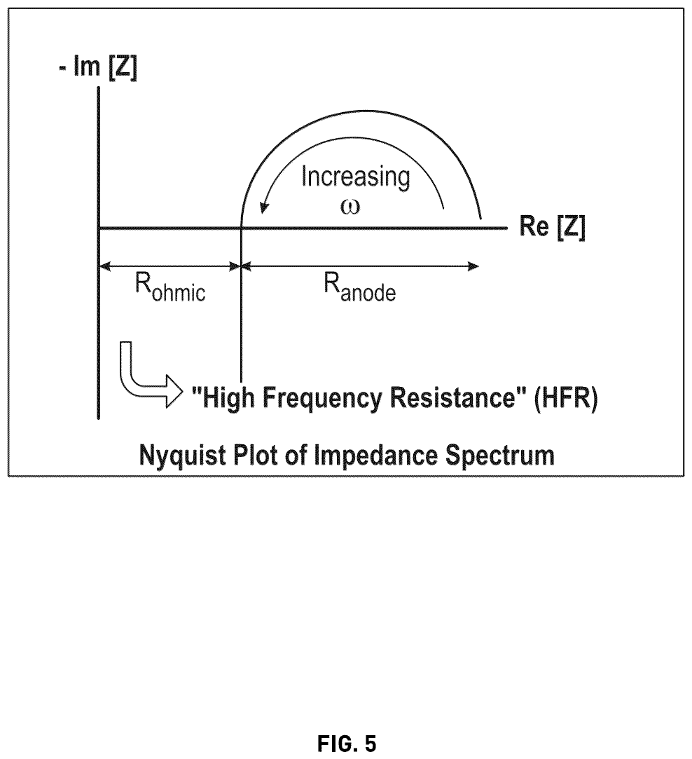

FIG. 5 shows an example of a theoretical Nyquist plot of an ideal electrolytic cell. FIG. 5 shows the real impedance (e.g., the resistance) and the imaginary impedance (e.g., the reactance) of an electrolytic cell across a range a frequencies (e.g., a frequency sweep). FIG. 5 shows that as the frequency increases, the resistance decreases before reaching a lower limit. The lower limit can represent R_ohmic, and the difference between the maximum resistance and the lower limit can represent R_anode. At a low frequency, the reactance can be approximately zero. As the frequency increases, the reactance can initially increase. Then the reactance can decrease to zero and continue decreasing past zero.

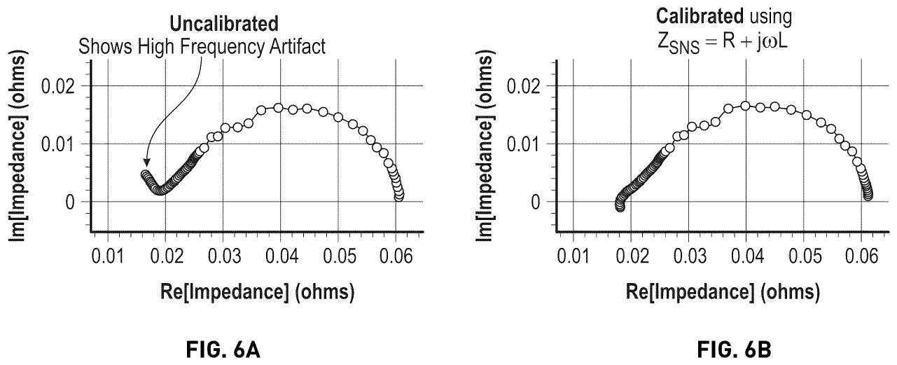

FIG. 6A shows an example of a measured uncalibrated impedance spectrum chart of an electrochemical cell. FIG. 6A shows an example where the parasitic inductance of the sensing impedance is not accounted for. FIG. 6A shows that there can be a high frequency artifact as a result of this uncalibrated inductance. This can reduce an accuracy of one or more determinations made using the data of FIG. 6A.

FIG. 6B shows an example of a calibrated impedance spectrum chart of an electrochemical cell. In the example of FIG. 6B, the system of FIG. 6A has been calibrated to account for the parasitic inductance in the sensing impedance. FIG. 6B shows that the high frequency artifact has been removed by the calibration. The data of FIG. 6B may provide a more accurate representation of one or more cell parameters when analyzed.

FIGS. 5-6B show impedance data, but a plot of the cell voltage across frequency can resemble or mirror the data of FIGS. 5-6B if the stimulus signal has an approximately equal magnitude across all frequencies. For example, the impedance data can be obtained by dividing cell voltage by cell current, and accordingly, if the cell current is the same for all frequencies, the voltage plot can have the same form as the impedance plot scaled by cell current value.

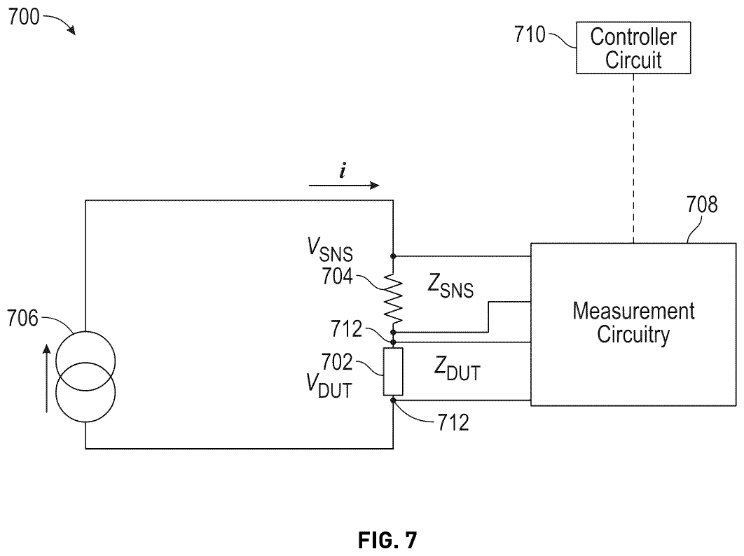

FIG. 7 shows an example of portions of an electrochemical monitoring system 700. FIG. 7 shows that the electrochemical monitoring system 700 can include measurement circuitry 708 and a controller circuit 710. The electrochemical monitoring system 700 can optionally include or be used in conjunction with an electrochemical cell 702, a sensing impedance 704, and a stimulus generation circuit 706. The electrochemical monitoring system 700 can be configured for determining one or more parameters of interest of an electrochemical cell. For example, the electrochemical monitoring system 700 can determine a direct parameter (e.g., an ECM parameter), or an inferred parameter (e.g., SoC, SoH).

The electrochemical cell 702 can include any electrochemical cell of interest, such as can include one or more cells of the PEMEL stack 114. The electrochemical cell 702 can include a series and/or parallel arrangement of electrochemical cells 702, or can include a single cell. The electrochemical cell 702 can be used in a system employing electrochemical cells, such as an electrolytic system.

The sensing impedance 704 can include any component or element with a non-zero impedance. For example, the sensing impedance 704 can include one or more of a wire, a resistor, a coil, an inductor, or a capacitor. The sensing impedance 704 can be arranged in series with the electrochemical cell 702. In an example, the sensing impedance 704 can be configured to provide an indication of the current through the electrochemical cell 702. For example, the voltage across the sensing impedance 704 can be indicative of the current through the 702, such as if the relationship between the voltage across the sensing impedance 704 and the current through the sensing impedance 704 has a defined relationship. In an example, the sensing impedance 704 can have a nominal resistance, R (e.g., as shown in FIG. 4). The nominal resistance can include a specified, calibrated, or measured value. The nominal resistance can have a specified precision. In an example, the sensing impedance 704 can include a reactance, Q. The reactance need not have a nominal value. The reactance need not have a specified, calibrated, or measured value. The reactance can include a parasitic reactance of the sensing impedance 704 or the installation conditions of the sensing impedance 704.

The stimulus generation circuit 706 can provide a stimulus (e.g., a stimulus current, a stimulus voltage) to the electrochemical cell 702, such as to make one or more EIS measurements or voltage measurements for use in an ECM technique (e.g., forcing the electrochemical cell 702 with a specific frequency or range of frequencies and measuring the response, such as to determine an EIS parameter or estimate one or more ECM parameters). The stimulus generation circuit 706 can include a stimulus current source or sink. The stimulus generation circuit 706 can be configured to provide a stimulus to the electrochemical cell 702 and to the sensing impedance 704. The stimulus generation circuit 706 can be coupled to the controller circuit 710. The controller circuit 710 can cause the stimulus generation circuit 706 to generate a stimulus (e.g., a stimulus signal). The controller circuit 710 can then determine a voltage across the electrochemical cell 702. The voltage across the electrochemical cell 702 can be used, such as used in conjunction with a voltage across the sensing impedance 704, to determine a parameter of the electrochemical cell 702.

The stimulus generation circuit 706 can provide a configurable stimulus, such as can be configured by a user, the controller circuit 710, or both. The stimulus generation circuit 706 can provide an AC stimulus, a DC stimulus, or both. The stimulus generation circuit 706 can provide a stimulus of a specified magnitude. The stimulus generation circuit 706 can provide an AC stimulus of a specified waveform. For example, the stimulus generation circuit 706 can provide an AC stimulus that is one or more of a sine wave, a square wave, a triangle wave, a sawtooth wave, or any other waveform. In an example, a square wave can be used, such as to force the electrochemical cell 702 across a range of frequencies (e.g., the frequency composition of the square wave).

The measurement circuitry 708 can be configured to obtain voltage measurements, current measurements, or both. The measurement circuitry 708 can be configured to obtain measurements at one or more alternating current (AC) frequencies, which can include a plurality of AC frequencies. For example, the measurement circuitry 708 can receive an indication of a specified AC frequency to make measurements at. The measurement circuitry 708 can be configured to make a first AC voltage measurement across nodes 712, which can be coupleable to the electrochemical cell 702 (e.g., the nodes 712 can be configured to be capable of being coupled to the electrochemical cell 702). For example, the nodes 712 can be coupled across the electrochemical cell 702 when the electrochemical monitoring system 700 is installed. The voltage measured in the first AC voltage measurement can be elicited in response to an AC stimulus injected through the electrochemical cell.

The measurement circuitry 708 can be configured to make a second AC voltage measurement across a sensing impedance. The voltage measured in the second AC voltage measurement can elicited in response to the AC stimulus. The sensing impedance can be coupled in series with the electrochemical cell 702. In an example, the first AC voltage measurement and the second AC voltage measurement can be made for one or more (e.g., a plurality of) specified AC frequencies. For example, the electrochemical monitoring system 700 can conduct a frequency sweep, which can include measuring the voltage across the electrochemical cell 702 and the sensing impedance 704 at a number of specified frequencies within a specified range of frequencies. This can include making measurements similar to an EIS sweep, however, the voltage values need not be converted to impedance values.

In an example, the first AC voltage measurement and the second AC voltage measurement can be made at two or more frequencies, which can include a plurality of frequencies. The plurality of frequencies can include a specified list of frequencies (e.g., configured by a user, configured by the controller circuit 710), a specified number of frequencies spread across a range (e.g., evenly spaced, logarithmically spaced, etc.), or any other set of frequencies. For example, the first AC voltage measurement and the second AC voltage measurement can be made at 100 frequencies between 0.1 hertz and 10,000 hertz.

The controller circuit 710 can include any circuit capable of performing instructions, and can include digital circuitry (e.g., digital logic, circuitry capable of executing digital instructions), analog logic, or both. The controller circuit 710 can be coupled to one or more of the measurement circuitry 708, the stimulus generation circuit 706, or one or more other circuits. In an example, one or more of the measurement circuitry 708, the stimulus generation circuit 706, the sensing impedance 704, or the controller circuit 710 can include one or more of each other or be included in one or more of each other. In an example, one or more of the controller circuit 710, the measurement circuitry 708, the stimulus generation circuit 706 or the sensing impedance 704 can be co-integrated (e.g., included on the same chip, performed or controlled by the same processor) or co-packaged (e.g., included in the same electronic packaging). In an example, one or more portions of the electrochemical monitoring system 700 (e.g., the controller circuit 710) can be implemented at least in part in the “cloud,” which can include using remote processing capabilities, such as over a network.

The controller circuit 710 can be configured to estimate model parameters corresponding to an equivalent circuit model (ECM) of the electrochemical cell 702 (e.g., such as shown and discussed with respect to FIG. 3), an ECM of the sensing impedance 704 (e.g., such as shown and discussed with respect to FIG. 4), or an ECM of a combination of the electrochemical cell 702 and the sensing impedance 704 (e.g., jointly estimating parameters corresponding to both the electrochemical cell 702 and the sensing impedance 704, such as using an ECM of the circuit of FIG. 3 in series with the circuit of FIG. 4). The controller circuit 710 can estimate the model parameters at least in part using the first AC voltage measurements, the second AC voltage measurements, or both, such as for one or more frequencies (e.g., for the plurality of specified AC frequencies). For example, the controller circuit 710 can receive or generate a plurality of first AC voltage measurements and second AC voltage measurements corresponding to a plurality of specified AC frequencies. These first and second AC voltage measurements at the plurality of specified AC frequencies can be used to jointly estimate model parameters for an ECM of the electrochemical cell 702, the sensing impedance 704, or both.

In an example, one or more of the first and second AC voltage measurements can be complex voltage values (e.g., containing magnitude and phase information). In this example, the phase information of the complex voltage values can be referenced relative to a reference phase derived from the AC stimulus. For example, the phase of the AC stimulus can be defined as zero and can comprise the reference phase. The first and second AC voltage measurements can indicate the phase of the voltages across the electrochemical cells 702 and sensing impedance 704, respectively, relative to the phase of the AC stimulus. In an example, one or more of the first AC voltage measurements and the second AC voltage measurements can include complex values defined by real and imaginary components.

The measurement circuitry 708 can include a synchronous demodulator circuit. The synchronous demodulator circuit can be configured to provide in-phase components, quadrature components, or both, using a input reference signal. The measurement circuitry 708 can use the synchronous demodulator circuit to obtain the first AC voltage measurement, the second AC voltage measurement, or both. For example, the first and second AC voltage measurements can be obtained using a synchronous demodulator circuit configured to provide in-phase and quadrature components of the first and second AC voltage measurements using the AC stimulus signal as an input reference signal.

In an example, the sensing impedance 704 can include a nominal resistance, such as discussed above. The ECM can model the sensing impedance 704 as the nominal resistance in series with a reactance. A value of the reactance (e.g., Q) can form one of the model parameters. The ECM model can account for the reactance of the sensing impedance 704 (e.g., such as can be caused by parasitic effects (e.g., a parasitic reactance, such as can be caused by lead wires, resistor material, or the effects of a surrounding installation (e.g., capacitance or inductance caused by positioning near a metallic enclosure wall))), which can help to allow the model to determine a better fit for the parameters of the electrochemical cell 702. This reactance parameter can provide a relaxation parameter, which can account for an effect of the physical system that would otherwise reduce an accuracy of the determined parameters of the electrochemical cell 702. In an example, the resistance of the sensing impedance 704 can comprise a model parameter too, such as when the nominal resistance is not specified.

In an example, the parameters of the ECM, alternatively or in addition to the parameters of the sensing impedance, can include one or more an ohmic resistance of a metallic electrochemical cell component (e.g., R_omhic), an anodic polarization resistance associated with the electrochemical cell (e.g., R_anode), a pseudo-capacitive interface parameter (e.g., Q_CPE), a constant phase element parameter (e.g., n_CPE), a parasitic reactance separate from the sense impedance (e.g., L_wire), or a parasitic element value associated with the monitoring circuitry, or combinations thereof. For example, the parameters of the ECM can include one or more parameters of the model shown in FIG. 3. It should be appreciated that the ECMs shown in FIG. 3 and FIG. 4 are illustrative only, and this disclosure applies to any ECM for modeling an electrochemical cell or a sensing impedance. For example, a battery cell can have a different ECM than the electrolytic ECM shown in FIG. 3. Another model can be used for the electrochemical cell, the sensing impedance, or both, such as can include a more accurate model, a more complex model, a simpler model, etc.

Potentially in contrast to a calibration methods that uses separate calibration procedures with specified precision reference elements, this approach can estimate Z_SNS (e.g., the impedance of the sensing impedance 704) directly from the first and second AC voltage measurements. The electrochemical monitoring system 700 can determine calibration parameters for the sensing impedance 704 simultaneously or at least partially concurrently with determining parameters of the electrochemical cell 702, such as can include electrolyzer impedance parameters. This joint estimation can be solved using various numerical methods such as gradient descent, Least Squares Fitting, or Markov Chain Monte Carlo methods.

For a specific frequency ω₁ (e.g., a first frequency), the voltage across the electrochemical cell 702 and the sensing impedance 704 can be represented by the current through the electrochemical cell 702 and the sensing impedance 704 (e.g., which can be identical if the electrochemical cell 702 and the sensing impedance 704 are in parallel) multiplied by the impedance of the electrochemical cell 702 and the sensing impedance 704, such as shown below:

$$\cdot V\_DUT ( {ω}_{1} ) = I \cdot Z\_DUT ( {ω}_{1} , R\_ohmic , R\_anode , n\_CPE , Q\_CPE , L\_wire )$$

$$\cdot V\_SNS ( {ω}_{1} ) = I \cdot Z\_SNS ( {ω}_{1} , Q )$$

The frequency ω₁ can affect both equations in specific ways. In the Z_DUT equation, the frequency ω₁ influences how each ECM parameter contributes to the overall impedance. For example, the R_ohmic component (ohmic resistance) can be largely frequency-independent, the R_anode and capacitive elements (represented by n_CPE and Q_CPE) can have frequency-dependent responses, and the inductive component L_wire can have an impedance that increases linearly with frequency (jω₁Lwire). In the Z_SNS equation, the frequency ω₁ can directly affect the reactive component, Z_SNS(ω₁, Q)=R+jω₁L. As frequency increases, the contribution of the inductive component (jω₁L) becomes more significant. When the stimulus generation circuit 706 applies this first frequency signal, the system can measure the resulting voltages VDUT(ω₁) (e.g., the first AC voltage measurement) and VSNS(ω₁) (e.g., the second AC voltage measurement). These measurements, along with the model equations, can form a system of equations with unknown parameters. In some cases, a single frequency can provide insufficient information to solve for all unknowns. Therefore, the stimulus generation circuit 706 can cycle through multiple frequencies (e.g., a frequency sweep, ω₁, ω₂, ω₃, . . . ), generating a system of equations:

$$\cdot VDUT ( {ω}_{2} ) = I \cdot ZDUT ( {ω}_{2} , R\_ohmic , R\_anode , n\_CPE , Q\_CPE , L\_wire )$$

$$\cdot VSNS ( {ω}_{2} ) = I \cdot ZSNS ( {ω}_{2} , Q )$$

And so on . . . .

This multi-frequency approach can create a determined or an overdetermined system, such as can be solved, such as through an optimization techniques to find the parameters (I, Q, R_ohmic, R_anode, n_CPE, Q_CPE, L_wire) that best fit all measurements across the frequency spectrum or fit the measurements to a specified degree. The frequency-dependent nature of both Z_DUT and Z_SNS can allow the system to distinguish between different parameters and estimate them jointly. By using measurements at multiple frequencies and a specified frequency-dependent behavior of the components, the system can separate the effects of the unknown reactance Q in the sense resistor from the parameters of the electrolyzer itself, such as without requiring a separate calibration procedure for the sensing impedance 704.

For joint estimation with the controller circuit 710, the optimization problem can be formulated to find the set of parameters (I, Q, R_ohmic, R_anode, n_CPE, Q_CPE, L_wire) that minimize the difference between the measured voltage data VDUT(ω) and VSNS(ω) from the frequency sweep and the modeled voltage measurements. This optimization can be solved using gradient descent, Least Squares Fitting, or Markov Chain Monte Carlo methods, such as while the electrochemical monitoring system 700 cycles through different frequencies.

One method to solve this optimization problem is through gradient descent. The controller circuit 710 can compute the gradient of the error function (the difference between measured and modeled voltages) with respect to each parameter and iteratively update the parameters in the direction that reduces the error. For example, starting with initial guesses for (I, a, R_ohmic, R_anode, n_CPE, Q_CPE, L_wire), the system can compute the modeled V_DUT(ω) and V_SNS(ω), can calculate the error compared to measured values, and can adjust the parameters proportionally to the gradient of the error. This process can repeat until convergence, such as when the change in error falls below a threshold (e.g., 0.1%).

Another approach is to use Least Squares Fitting, where the system can minimize the L2 norm between the measured spectrum and the modeled spectrum. This can be implemented with various weighting strategies, for instance, applying a higher weight to the imaginary impedance component than to the real component, or weighting different frequencies differently based on their importance for electrolyzer health monitoring. The determination of parameters that minimize this loss can be done via gradient descent using backpropagation, or directly through matrix operations for linear components of the model.

Markov Chain Monte Carlo (MCMC) methods offer another solution approach, which can be particularly valuable when dealing with noisy measurements. MCMC methods can generate samples from the posterior distribution of the parameters given the measured data, which can help to allow estimation of not just the optimal parameter values but also their uncertainty. This approach might start with prior distributions for each parameter (e.g., uniform distributions within physically reasonable ranges) and use algorithms like Metropolis-Hastings to sample the parameter space, accepting or rejecting proposed parameter sets based on how well they explain the measured data.

For real-time implementation in an electrochemical monitoring system 700, the optimization problem can be simplified by using domain knowledge. For example, if certain parameters are known to vary slowly (e.g., R_ohmic), they can be updated less frequently than others. Additionally, the optimization can be initialized with parameter values from previous measurements, which can reduce computation time. The system might also implement a multi-stage approach, first estimating the most critical parameters (e.g., those related to the sense resistor) before refining estimates of all parameters. In an example, initial “guess” values for one or more parameters can be input by a user or determined based on the electrochemical cell 702 or the sensing impedance 704.

The accuracy of this joint estimation approach can be validated using synthetic data, such as where known parameter values are used to generate simulated voltage measurements, and then the optimization algorithm can attempt to recover these known values. This validation can be performed across different operating conditions (e.g., varying current densities, temperatures), which can help to ensure robustness. In practice, this approach has been shown to improve some determinations about an electrochemical cell (e.g., improved impedance measurement accuracy) as compared to uncalibrated measurements, particularly at higher frequencies where the effect of unspecified inductive components in a sense resistor can be most pronounced.

One advantage of this approach is that it can remove a need or desire for expensive reference equipment and/or separate calibration procedures. Other approaches to calibration can be benefitted by a system to produce a reference element or very expensive tight tolerance resistors, which can constrain system performance and limits scalability. Furthermore, the ECM estimation can adapt to changing operating conditions. Since the sensing impedance 704 impedance characteristics may change with temperature or other environmental factors during operation, the ability to estimate both Z_DUT and Z_SNS can help to provides a more accurate Z_SNS value, such as reflecting current conditions. This can lead to better health monitoring and more timely preventative maintenance of the sensing impedance 704 or electrolyzer system.

In an example, the controller circuit 710 can be configured to estimate the model parameters by executing a numerical approach. The numerical approach can include an iterative numerical approach, such as can be configured to iteratively estimate model parameters of the ECM. The numerical approach can estimate model parameters that best correspond to the one or more of the first and second AC voltage measurements for the plurality of specified AC frequencies. For example, the numerical approach can consider all of the first and second AC voltage measurements or a subset of the first and second AC voltage measurements.

The controller circuit 710 can be configured to terminate the iterative estimation in response to meeting a criterion. The criterion can correspond to a goodness of fit between the first and second AC voltage measurements for the plurality of specified AC frequencies and candidate first and second AC voltage measurements generated using candidate estimated model parameters of the ECM. The criterion can include comparing a goodness of fit indication to a threshold value. The threshold value can correspond to an R² value or a value of a metric corresponding to a cost function (e.g., any function for mapping a difference to an error or “cost”). For example, the controller circuit 710 can determine a goodness-of-fit (e.g., an indication of the difference) between the first and second voltage values at the plurality of specified AC frequencies determined by the ECM and the measured first and second AC voltage measurements (e.g., an R² error), and terminate when this difference is below a threshold.

In an example, the controller circuit 710 can be configured to jointly estimate model parameters of the equivalent circuit model (ECM) of one or more additional electrochemical cells and the sensing impedance using corresponding AC voltage measurements. For example, the measurement circuitry 708 can be configured to measure the voltage across one or more additional electrochemical cells (e.g., individual cells or electrochemical cell groups), such as can be arranged in series with the sensing impedance 704. The voltage values of the additional electrochemical cells can be measured similarly to the electrochemical cell 702. The controller circuit 710 can determine parameters corresponding to the additional electrochemical cells similarly to those determined for the electrochemical cell 702, such as using voltage measurements corresponding to the additional electrochemical cells.

In an example, the electrochemical monitoring system 700 can include one or more of the stimulus generation circuit 706, the electrochemical cell 702, the sensing impedance 704, or one or more additional components.

In an example, the electrochemical cell can include one or more of a battery cell, a fuel cell, or an electrolysis cell.

In an example, the controller circuit 710 can be configured to establish a calibrated (e.g., such as would have been determined using a calibrated sensing impedance 704) impedance versus frequency of the electrochemical cell 702, such as using the model parameters and/or one or more of the first AC voltage measurements or the second AC voltage measurements. For example, the model parameters of the electrochemical cell 702 can allow the controller circuit 710 to construct a theoretical impedance versus frequency of the electrochemical cell 702 (e.g., by determining the frequency of the model of FIG. 3 with the determined parameters at a plurality of specified AC frequencies). In an example, the controller circuit 710 can establish a calibrated impedance versus frequency of the electrochemical cell 702 by using the determined model parameters of the sensing impedance 704 to determine the stimulus current value for each of the plurality of specified AC frequencies, and then using these determined current values to determine the impedance of the electrochemical cell 702 at each frequency using corresponding first AC voltage measurements at each frequency. Following establishing a calibrated impedance versus frequency, the impedance profile can be used similarly to an EIS spectrum, such as in an EIS operation (e.g., to determine one or more EIS model parameters).

In an example, the ECM model parameters can be used directly to determine one or more properties of the electrochemical cell 702, such as without determining an impedance value of the electrochemical cell 702. In an example, one or more of the model parameters can comprise a feature of interest. In an example, one or more model parameters can be combined, such as with other measured or specified values, to determine a feature of interest.

In an example, the controller circuit can be configured to provide the model parameters to a classifier as an input. The classifier can be configured to generate an output comprising an indication of a state of the electrochemical cell 702. The state can include an indication of one or more of the SoH, SoC, or other parameter of the electrochemical cell 702. In an example, the state can indicate whether an anomaly exists with respect to the electrochemical cell. The anomaly can include one or more of an indication of a poor state of health, an indication of a hole in a cell plate, an indication of a membrane perforation, or an indication of a water contaminated cell. In an example, the state of the electrochemical cell 702 can indicate that the electrochemical cell 702 can be benefitted by maintenance or replacement.

In an example, the classifier can include a binary classifier. In an example, the classifier can compare a parameter (e.g., an ECM parameter, a R² value) to a threshold, and determine the state based on whether the parameter is above or below the threshold. For example, when the parameter estimation produces a model that well fits the data, this can be an indication that the electrochemical cell 702 is operating normally. When the parameter estimation produces a model that does not well fit the data, this can be an indication that the electrochemical cell 702 is not operating normally, or is anomalous. The classifier can compare a goodness-of-fit metric to a threshold, and return a “baseline” state when the goodness-of-fit metric indicates a fit better than the threshold and return an “anomalous” state when the goodness-of-fit metric indicates a fit worse than the threshold.

In an example, a classifier or machine learning algorithm can operate directly on the first AC voltage measurements, the second AC voltage measurements, or both, such as to determine a feature of interest of the electrochemical cell 702 or an indication of the state of the electrochemical cell 702.

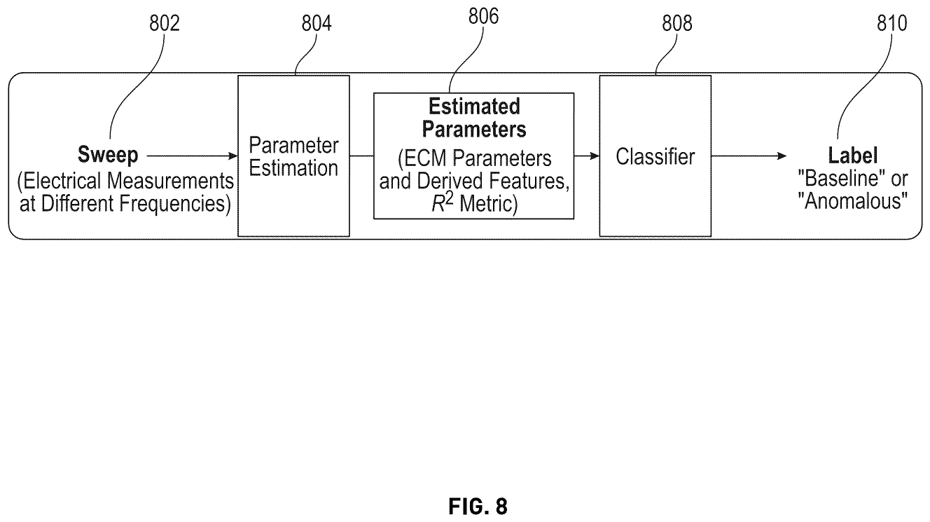

FIG. 8 shows an example of portions of a block diagram of an electrochemical monitoring system 700. At block 802, a sweep can be conducted, such as can include determining the voltage across one or more of the electrochemical cell 702 or the sensing impedance 704 at a plurality of specified AC frequencies (e.g., determining the first AC voltage measurements and the second AC voltage measurements).

At block 804, parameters of an ECM can be estimated. This can include jointly estimating ECM parameters of a model corresponding to the electrochemical cell 702 and the sensing impedance 704, or jointly estimating parameters of models corresponding to the electrochemical cell 702 and the sensing impedance 704.

At block 806, the parameters of the ECM can be received. Alternatively or additionally, a goodness-of-fit metric (e.g., an R² value) can be received or determined.

At block 808, a classifier can be used on one or more of the ECM parameters, the goodness-of-fit metric, or both. The classifier can be any type of classifier, and can include machine learning aspects.

At block 810, the electrochemical cell 702 can be labeled, such as can include labeling the cell as “baseline” (e.g., normal) or “anomalous” (e.g., the cell may need maintenance or replacement).

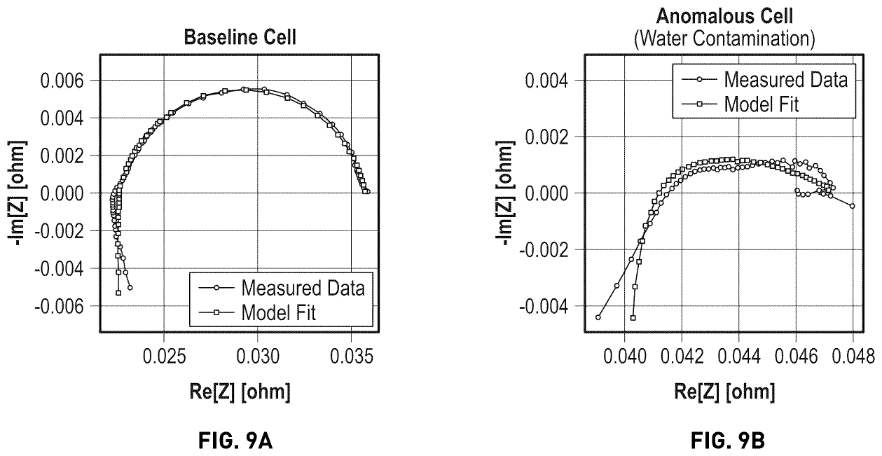

FIG. 9A shows an example of a Nyquist plot of a baseline cell. FIG. 9A shows the measured data and the data predicted by the determined model parameters (e.g., model parameters determined as discussed herein). FIG. 9A shows that the fit between the measured data and the predicted data is relatively good, such as can result in a goodness-of-fit metric indicating a relatively good fit (e.g., a relatively low R² value). This goodness-of-fit metric, alternatively or in addition to one or more model parameters or other pieces of information, can be used to determine that the electrochemical cell 702 is operating normally (e.g., in a baseline state).

FIG. 9B shows an example of a Nyquist plot of an anomalous cell. FIG. 9B shows the measured data and the data predicted by the determined model parameters (e.g., model parameters determined as discussed herein). FIG. 9B shows that the fit between the measured data and the predicted data is relatively poor, such as can result in a goodness-of-fit metric indicating a relatively poor fit (e.g., a relatively high R² value). This goodness-of-fit metric, alternatively or in addition to one or more model parameters or other pieces of information, can be used to determine that the electrochemical cell 702 is operating in an anomalous or non-baseline state.

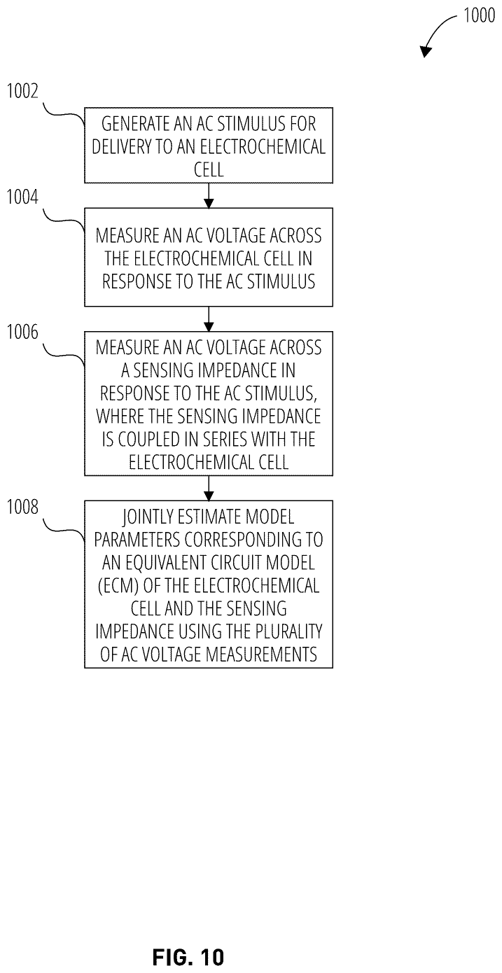

FIG. 10 shows an example of portions of a method 1000 for operating an electrochemical monitoring system, such as the electrochemical monitoring system 700. The method 1000 can include a method for determining one or more parameters of interest of an electrochemical cell. At step 1002, an AC stimulus can be generated for delivery to an electrochemical cell. The AC stimulus can have one or more of a specified frequency, a specified amplitude, or a specified phase. The ac stimulus signal can be generated by a stimulus generation circuit.

At step 1004, an AC voltage across the electrochemical cell in response to the AC stimulus can be measured. The electrochemical cell can include any type of electrochemical cell, such as an electrolysis cell. The AC voltage across the electrochemical cell at the specified frequency can be measured to determine the response of the electrochemical cell to the AC stimulus. In an example, the AC voltage can include a complex value, such as including an indication of the respective phases of the AC stimulus and the voltage across the electrochemical cell.

At step 1006, an AC voltage across a sensing impedance in response to the AC stimulus can be measured, where the sensing impedance can be coupled in series with the electrochemical cell. The sensing impedance can include any component or element with a non-zero impedance. The AC voltage across the sensing impedance at the specified frequency can be measured to determine the response of the sensing impedance to the AC stimulus. In an example, the AC voltage can include a complex value, such as including an indication of the respective phases of the AC stimulus and the voltage across the sensing impedance.

In an example, one or more (e.g., all) of steps 1002 through 1006 can be performed at one or more (e.g., a plurality) of specified AC frequencies. For example, steps 1002 through 1006 can be performed for each frequency in a frequency sweep.

At step 1008, model parameters corresponding to an equivalent circuit model (ECM) of the electrochemical cell and the sensing impedance can be jointly estimated using the plurality of AC voltage measurements (e.g., the voltages across the electrochemical cell and the sensing impedance at the plurality of specified AC frequencies). For example, the plurality of AC voltage measurements can used by a fitting technique to determine one or more model parameters of best fit. In an example, the sensing impedance can include a nominal resistance and the ECM can model the sensing impedance as the nominal resistance in series with a reactance, wherein a value of the reactance comprises one of the model parameters.

The shown order of steps is not intended to be a limitation on the order in which the steps are performed. In an example, two or more steps may be performed simultaneously or at least partially concurrently.

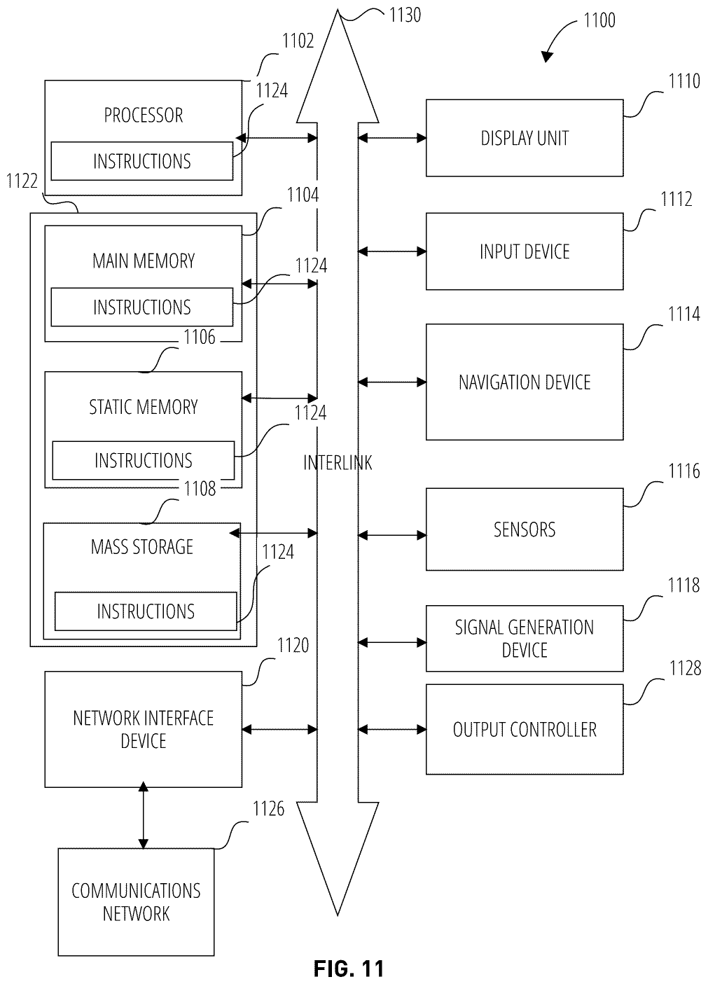

FIG. 11 illustrates a block diagram of an example machine 1100 upon which any one or more of the techniques (e.g., methodologies) discussed herein may be implemented. Examples, as described herein, may include, or may operate by, logic or a number of components, or mechanisms in the machine 1100. Circuitry (e.g., processing circuitry) is a collection of circuits implemented in tangible entities of the machine 1100 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 1100 follow.

In alternative examples, the machine 1100 may operate as a standalone device or may be connected (e.g., networked) to other machines. In a networked deployment, the machine 1100 may operate in the capacity of a server machine, a client machine, or both in server-client network environments. In an example, the machine 1100 may act as a peer machine in peer-to-peer (P2P) (or other distributed) network environment. The machine 1100 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 1100 may include a hardware processor 1102 (e.g., a central processing unit (CPU), a graphics processing unit (GPU), a hardware processor core, or any combination thereof), a main memory 1104, a static memory (e.g., memory or storage for firmware, microcode, a basic-input-output (BIOS), and mass storage 1108 (e.g., hard drives, tape drives, flash storage, or other block devices) some or all of which may communicate with each other via an interlink 1130 (e.g., bus). The machine 1100 may further include a display unit 1110, an alphanumeric input device 1112 (e.g., a keyboard), and a user interface (UI) navigation device 1114 (e.g., a mouse). In an example, the display unit 1110, input device 1112 and UI navigation device 1114 may be a touch screen display. The machine 1100 may additionally include a signal generation device 1118 (e.g., a speaker), a network interface device 1120, and one or more sensors 1116, such as a global positioning system (GPS) sensor, compass, accelerometer, or other sensor. The machine 1100 may include an output controller 1128, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 1102, the main memory 1104, the static memory 1106, or the mass storage 1108 may be, or include, a machine readable medium 1122 on which is stored one or more sets of data structures or instructions 1124 (e.g., software) embodying or utilized by any one or more of the techniques or functions described herein. The instructions 1124 may also reside, completely or at least partially, within any of registers of the processor 1102, the main memory 1104, the static memory 1106, or the mass storage 1108 during execution thereof by the machine 1100. In an example, one or any combination of the hardware processor 1102, the main memory 1104, the static memory 1106, or the mass storage 1108 may constitute the machine readable media 1122. While the machine readable medium 1122 is illustrated as a single medium, the term “machine readable medium” may include a single medium or multiple media (e.g., a centralized or distributed database, and/or associated caches and servers) configured to store the one or more instructions 1124.

The term “machine readable medium” may include any medium that is capable of storing, encoding, or carrying instructions for execution by the machine 1100 and that cause the machine 1100 to perform any one or more of the techniques of the present disclosure, or that is capable of storing, encoding or carrying data structures used by or associated with such instructions. Non-limiting machine readable medium examples may include solid-state memories, optical media, magnetic media, and signals (e.g., radio frequency signals, other photon based signals, sound signals, etc.). In an example, a non-transitory machine readable medium comprises a machine readable medium with a plurality of particles having invariant (e.g., rest) mass, and thus are compositions of matter. Accordingly, non-transitory machine-readable media are machine readable media that do not include transitory propagating signals. Specific examples of non-transitory machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

In an example, information stored or otherwise provided on the machine readable medium 1122 may be representative of the instructions 1124, such as instructions 1124 themselves or a format from which the instructions 1124 may be derived. This format from which the instructions 1124 may be derived may include source code, encoded instructions (e.g., in compressed or encrypted form), packaged instructions (e.g., split into multiple packages), or the like. The information representative of the instructions 1124 in the machine readable medium 1122 may be processed by processing circuitry into the instructions to implement any of the operations discussed herein. For example, deriving the instructions 1124 from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 1124.

In an example, the derivation of the instructions 1124 may include assembly, compilation, or interpretation of the information (e.g., by the processing circuitry) to create the instructions 1124 from some intermediate or preprocessed format provided by the machine readable medium 1122. The information, when provided in multiple parts, may be combined, unpacked, and modified to create the instructions 1124. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 1124 may be further transmitted or received over a communications network 1126 using a transmission medium via the network interface device 1120 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), LoRa/LoRaWAN, or satellite communication networks, mobile telephone networks (e.g., cellular networks such as those complying with 3G, 4G LTE/LTE-A, or 5G standards), Plain Old Telephone (POTS) networks, and wireless data networks (e.g., Institute of Electrical and Electronics Engineers (IEEE) 802.11 family of standards known as Wi-Fi®, IEEE 802.15.4 family of standards, peer-to-peer (P2P) networks, among others. In an example, the network interface device 1120 may include one or more physical jacks (e.g., Ethernet, coaxial, or phone jacks) or one or more antennas to connect to the communications network 1126. In an example, the network interface device 1120 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 1100, and includes digital or analog communications signals or other intangible medium to facilitate communication of such software. A transmission medium is a machine-readable medium.

The following, non-limiting examples, detail certain aspects of the present subject matter to solve the challenges and provide the benefits discussed herein, among others.

### EXAMPLES

Example 1 is an electrochemical monitoring system for determining one or more parameters of interest of an electrochemical cell, the electrochemical monitoring system comprising: measurement circuitry, configured to obtain, for a plurality of specified alternating current (AC) frequencies: a first AC voltage measurement across nodes coupleable to the electrochemical cell, the first AC voltage measurement elicited in response to an AC stimulus injected through the electrochemical cell; and a second AC voltage measurement across a sensing impedance elicited in response to the AC stimulus, wherein the sensing impedance is coupled in series with the electrochemical cell; and a controller circuit, configured to: jointly estimate model parameters corresponding to an equivalent circuit model (ECM) of a combination of the electrochemical cell and the sensing impedance using the first and second AC voltage measurements for the plurality of specified AC frequencies; and wherein the first and second AC voltage measurements contain magnitude and phase information, the phase information relative to a reference phase derived from the AC stimulus.

In Example 2, the subject matter of Example 1 optionally includes wherein: the sensing impedance comprises a nominal resistance; and the ECM models the sensing impedance as the nominal resistance in series with a reactance, wherein a value of the reactance comprises one of the model parameters.

In Example 3, the subject matter of Example 2 optionally includes wherein: the reactance corresponds to a parasitic reactance.

In Example 4, the subject matter of any one or more of Examples 2-3 optionally include wherein parameters of the ECM other than the sensing impedance comprise one or more an ohmic resistance of a metallic electrochemical cell component, an anodic polarization resistance associated with the electrochemical cell, a pseudo-capacitive interface parameter, a constant phase element parameter, a parasitic reactance separate from the sense impedance, or a parasitic element value associated with the monitoring circuitry, or combinations thereof.

In Example 5, the subject matter of any one or more of Examples 1-4 optionally include wherein the control controller circuit is configured to: jointly estimate the model parameters by executing a numerical approach to iteratively estimate model parameters of the ECM that best correspond to the first and second AC voltage measurements for the plurality of specified AC frequencies.

In Example 6, the subject matter of Example 5 optionally includes wherein the controller circuit is configured to: terminate the iterative estimation in response to meeting a criterion corresponding to a goodness of fit between the first and second AC voltage measurements for the plurality of specified AC frequencies, or impedance values derived therefrom, and candidate first and second AC voltage measurements generated using candidate estimated model parameters of the ECM.

In Example 7, the subject matter of Example 6 optionally includes wherein the criterion comprises comparing a goodness of fit indication to a threshold value.

In Example 8, the subject matter of Example 7 optionally includes value or a value of a metric corresponding to a cost function.

In Example 9, the subject matter of any one or more of Examples 1-8 optionally include wherein the first and second AC voltage measurements comprise complex values defined by real and imaginary components.

In Example 10, the subject matter of Example 9 optionally includes wherein the first and second AC voltage measurements are obtained using a synchronous demodulator circuit configured to provide in-phase and quadrature components of the first and second AC voltage measurements using the AC stimulus as an input reference signal.

In Example 11, the subject matter of any one or more of Examples 1-10 optionally include wherein: wherein the controller circuit is configured to jointly estimate model parameters of equivalent circuit model (ECM) of one or more additional electrochemical cells and the sensing impedance using corresponding AC voltage measurements.

In Example 12, the subject matter of any one or more of Examples 1-11 optionally include a stimulus generation circuit configured to generate an AC current as the AC stimulus.

In Example 13, the subject matter of any one or more of Examples 1-12 optionally include the electrochemical cell.

In Example 14, the subject matter of Example 13 optionally includes wherein the electrochemical cell comprises a battery cell, a fuel cell, or an electrolysis cell.

In Example 15, the subject matter of any one or more of Examples 1-14 optionally include wherein the controller circuit is configured to establish a calibrated impedance versus frequency of the electrochemical cell using the model parameters and at least the first AC voltage measurements.

In Example 16, the subject matter of any one or more of Examples 1-15 optionally include wherein: the controller circuit is configured to provide the model parameters to a classifier as an input; and the classifier is configured to generate an output comprising an indication of a state of the electrochemical cell.

In Example 17, the subject matter of Example 16 optionally includes wherein the state indicates whether an anomaly exists with respect to the electrochemical cell.

Example 18 is an method for determining one or more parameters of interest of an electrochemical cell, the method comprising: at a plurality of specified alternating current (AC) frequencies: generating an AC stimulus for delivery to an electrochemical cell; measuring an AC voltage across the electrochemical cell in response to the AC stimulus; and measuring an AC voltage across a sensing impedance in response to the AC stimulus, wherein the sensing impedance is coupled in series with the electrochemical cell; and jointly estimating model parameters corresponding to an equivalent circuit model (ECM) of the electrochemical cell and the sensing impedance using the plurality of AC voltage measurements.

In Example 19, the subject matter of Example 18 optionally includes wherein: the sensing impedance comprises a nominal resistance; and the ECM models the sensing impedance as the nominal resistance in series with a reactance, wherein a value of the reactance comprises one of the model parameters.

Example 20 is an electrochemical monitoring system for determining one or more parameters of interest of an electrochemical cell, the electrochemical monitoring system comprising: measurement circuitry, configured to obtain, for a plurality of specified alternating current (AC) frequencies: a first AC voltage measurement across nodes coupleable to the electrochemical cell, the first AC voltage measurement elicited in response to an AC stimulus injected through the electrochemical cell; and a second AC voltage measurement across a sensing impedance elicited in response to the AC stimulus, wherein the sensing impedance is coupled in series with the electrochemical cell; and a controller circuit, configured to: jointly estimate model parameters corresponding to an equivalent circuit model (ECM) of a combination of the electrochemical cell and the sensing impedance using the first and second AC voltage measurements for the plurality of specified AC frequencies; and wherein: the first and second AC voltage measurements contain magnitude and phase information, the phase information relative to a reference phase derived from the AC stimulus; the sensing impedance comprises a nominal resistance; the ECM models the sensing impedance as the nominal resistance in series with a reactance, wherein a value of the reactance comprises one of the model parameters; and the controller circuit is configured to establish a calibrated impedance versus frequency of the electrochemical cell using the model parameters and at least the first AC voltage measurements.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific examples that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the terms “or” and “and/or” are used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5). Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4).

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like.

Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other examples may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the examples should be determined with reference to the appended claims, along with the full scope of equivalents to which such claims are entitled.

What is claimed is:

1. An electrochemical monitoring system for determining one or more parameters of interest of an electrochemical cell, the electrochemical monitoring system comprising:
measurement circuitry, configured to obtain, for a plurality of specified alternating current (AC) frequencies:
a first AC voltage measurement across nodes coupleable to the electrochemical cell, the first AC voltage measurement elicited in response to an AC stimulus injected through the electrochemical cell; and
a second AC voltage measurement across a sensing impedance elicited in response to the AC stimulus, wherein the sensing impedance is coupled in series with the electrochemical cell; and
a controller circuit, configured to:
jointly estimate model parameters corresponding to an equivalent circuit model (ECM) of a combination of the electrochemical cell and the sensing impedance using the first and second AC voltage measurements for the plurality of specified AC frequencies; and
wherein the first and second AC voltage measurements contain magnitude and phase information, the phase information relative to a reference phase derived from the AC stimulus.

2. The electrochemical monitoring system of claim 1, wherein:
the sensing impedance comprises a nominal resistance; and
the ECM models the sensing impedance as the nominal resistance in series with a reactance, wherein a value of the reactance comprises one of the model parameters.

3. The electrochemical monitoring system of claim 2, wherein:
the reactance corresponds to a parasitic reactance.

4. The electrochemical monitoring system of claim 2, wherein parameters of the ECM other than the sensing impedance comprise one or more an ohmic resistance of a metallic electrochemical cell component, an anodic polarization resistance associated with the electrochemical cell, a pseudo-capacitive interface parameter, a constant phase element parameter, a parasitic reactance separate from the sense impedance, or a parasitic element value associated with the monitoring circuitry, or combinations thereof.

5. The electrochemical monitoring system of claim 1, wherein the control controller circuit is configured to:
jointly estimate the model parameters by executing a numerical approach to iteratively estimate model parameters of the ECM that best correspond to the first and second AC voltage measurements for the plurality of specified AC frequencies.

6. The electrochemical monitoring system of claim 5, wherein the controller circuit is configured to:
terminate the iterative estimation in response to meeting a criterion corresponding to a goodness of fit between the first and second AC voltage measurements for the plurality of specified AC frequencies, or impedance values derived therefrom, and candidate first and second AC voltage measurements generated using candidate estimated model parameters of the ECM.

7. The electrochemical monitoring system of claim 6, wherein the criterion comprises comparing a goodness of fit indication to a threshold value.

8. The electrochemical monitoring system of claim 7, wherein the threshold value corresponds to an R² value or a value of a metric corresponding to a cost function.

9. The electrochemical monitoring system of claim 1, wherein the first and second AC voltage measurements comprise complex values defined by real and imaginary components.

10. The electrochemical monitoring system of claim 9, wherein the first and second AC voltage measurements are obtained using a synchronous demodulator circuit configured to provide in-phase and quadrature components of the first and second AC voltage measurements using the AC stimulus as an input reference signal.

11. The electrochemical monitoring system of claim 1, wherein:
wherein the controller circuit is configured to jointly estimate model parameters of equivalent circuit model (ECM) of one or more additional electrochemical cells and the sensing impedance using corresponding AC voltage measurements.

12. The electrochemical monitoring system of claim 1, comprising:
a stimulus generation circuit configured to generate an AC current as the AC stimulus.

13. The electrochemical monitoring system of claim 1, further comprising the electrochemical cell.

14. The electrochemical monitoring system of claim 13, wherein the electrochemical cell comprises a battery cell, a fuel cell, or an electrolysis cell.

15. The electrochemical monitoring system of claim 1, wherein the controller circuit is configured to establish a calibrated impedance versus frequency of the electrochemical cell using the model parameters and at least the first AC voltage measurements.

16. The electrochemical monitoring system of claim 1, wherein:
the controller circuit is configured to provide the model parameters to a classifier as an input; and
the classifier is configured to generate an output comprising an indication of a state of the electrochemical cell.

17. The electrochemical monitoring system of claim 16, wherein the state indicates whether an anomaly exists with respect to the electrochemical cell.

18. An method for determining one or more parameters of interest of an electrochemical cell, the method comprising:
at a plurality of specified alternating current (AC) frequencies:
generating an AC stimulus for delivery to an electrochemical cell;
measuring an AC voltage across the electrochemical cell in response to the AC stimulus; and
measuring an AC voltage across a sensing impedance in response to the AC stimulus, wherein the sensing impedance is coupled in series with the electrochemical cell; and
jointly estimating model parameters corresponding to an equivalent circuit model (ECM) of the electrochemical cell and the sensing impedance using the plurality of AC voltage measurements.

19. The method of claim 18, wherein:
the sensing impedance comprises a nominal resistance; and
the ECM models the sensing impedance as the nominal resistance in series with a reactance, wherein a value of the reactance comprises one of the model parameters.

20. An electrochemical monitoring system for determining one or more parameters of interest of an electrochemical cell, the electrochemical monitoring system comprising:
measurement circuitry, configured to obtain, for a plurality of specified alternating current (AC) frequencies:
a first AC voltage measurement across nodes coupleable to the electrochemical cell, the first AC voltage measurement elicited in response to an AC stimulus injected through the electrochemical cell; and
a second AC voltage measurement across a sensing impedance elicited in response to the AC stimulus, wherein the sensing impedance is coupled in series with the electrochemical cell; and
a controller circuit, configured to:
jointly estimate model parameters corresponding to an equivalent circuit (ECM) of a combination of the electrochemical cell and the sensing impedance using the first and second AC voltage measurements for the plurality of specified AC frequencies; and
wherein:
the first and second AC voltage measurements contain magnitude and phase information, the phase information relative to a reference phase derived from the AC stimulus;
the sensing impedance comprises a nominal resistance;
the ECM models the sensing impedance as the nominal resistance in series with a reactance, wherein a value of the reactance comprises one of the model parameters; and
the controller circuit is configured to establish a calibrated impedance versus frequency of the electrochemical cell using the model parameters and at least the first AC voltage measurements.
